(19) United States
(12) Patent Application Publication
(10) Pub. No.: US 2026/0045918 A1
(43) Pub. Date: Feb. 12, 2026

(54) ENVELOPE TRACKING BIAS ADDER

(71) Applicant: SKYWORKS SOLUTIONS, INC., Irvine, CA (US)

(72) Inventors: Nathan Lucas Nuzum, Quasqueton, IA (US); Gregory A. Blum, Cedar Rapids, IA (US)

(21) Appl. No.: 19/289,282

(22) Filed: Aug. 4, 2025

Related U.S. Application Data
(60) Provisional application No. 63/680,682, filed on Aug. 8, 2024.

(51) Int. Cl. H03F 1/30; H03F 3/24

(52) U.S. Cl. CPC H03F 1/301; H03F 3/245; H03F 2200/102; H03F 2200/21

(57) ABSTRACT

A bias adder system for adjusting the bias of a circuit. The system includes an amplifier; an input node configured to receive a supply voltage; an output node coupled to an inverting input of the amplifier and configured to provide an output current; a reference node configured to provide a reference voltage; a first transistor coupled between the input node and the inverting input of the amplifier; and a second transistor coupled between the reference node and a non-inverting input of the amplifier.

### CROSS-REFERENCE TO RELATED APPLICATIONS

This application claims priority under 35 U.S.C. § 119 (e) to U.S. Provisional Patent Application 63/680,682, titled ENVELOPE TRACKING BIAS ADDER, which was filed on Aug. 8, 2024, and which is hereby incorporated by reference in its entirety for all purposes.

### BACKGROUND

### 1. Field of the Disclosure

At least one example in accordance with the present disclosure relates generally to controlling the bias of amplifiers in electronic systems.

### 2. Discussion of Related Art

Power amplifiers are used in telecommunication and audio systems, and other electronic systems, to amplify low power signals into high power signals.

### SUMMARY

According to at least one aspect of the present disclosure a bias adder system is presented, comprising: an amplifier; an input node configured to receive a supply voltage; an output node coupled to an inverting input of the amplifier and configured to provide an output current; a reference node configured to provide a reference voltage; a first transistor coupled between the input node and the inverting input of the amplifier; and a second transistor coupled between the reference node and a non-inverting input of the amplifier.

In some examples, the bias adder system further comprises a third transistor and a fourth transistor coupled in series with one another between the inverting input and the non-inverting input of the amplifier. In some examples, the bias adder system further comprises a power source coupled to the reference node and to a first gate of the first transistor and a second gate of the second transistor, the power source being configured to provide a first gate voltage to the first gate and the second gate. In some examples, an output of the amplifier is coupled to a third gate of the third transistor and to a fourth gate of the fourth transistor. In some examples, the bias adder system further comprises a first resistor coupled between the first transistor and the inverting input of the amplifier, and a second resistor coupled between the second transistor and the non-inverting input of the amplifier. In some examples, the output node is further coupled to an amplifier circuit and configured to provide the output current to an input of the power amplifier circuit to adjust a bias voltage of the power amplifier circuit. In some examples, the power amplifier circuit includes a bias circuit configured to receive the output current and to generate a bias voltage based at least in part on the output current.

According to at least one aspect of the present disclosure, a system for adjusting a bias voltage of an amplifier is presented. The system comprises a resistor array; a DC current DAC coupled to the resistor array; an offset adjustment circuit coupled to the resistor array; an output coupled to the DC current DAC; and a controller.

In some examples, the output is further coupled to an amplifier circuit and is configured to provide a current to an input of the amplifier circuit. In some examples, the amplifier circuit includes a bias circuit coupled to the output and configured to generate a bias voltage based at least in part on the current. In some examples, the controller is configured to control a trim of the resistor array, and to control the offset adjustment circuit to provide a voltage offset to the resistor array to determine a bias level of the DC current DAC. In some examples, the DC current DAC is configured to provide a current to the output.

According to at least one aspect of the present disclosure, a method for providing a bias voltage is presented, comprising: selectively opening and closing a first group of transistors coupled between an inverting input of an amplifier and a supply voltage node; selectively opening and closing a second group of transistors coupled between a non-inverting input of the amplifier and a reference voltage node; providing a first voltage at the inverting input based on an open or closed state of the first group of transistors; providing a second voltage at the non-inverting input based on an open or closed state of the second group of transistors; providing a third voltage at an output of the amplifier, the third voltage being based at least in part on a difference between the first voltage and the second voltage; selectively coupling the inverting input to the non-inverting input of the amplifier based on the third voltage; and providing a current at an output, the current being based on the first voltage, the second voltage, and the third voltage.

In some examples, selectively opening and closing the first group of transistors and selectively opening and closing the second group of transistors is based on a duty cycle of a power source. In some examples, the power source is configured to provide a control voltage to gates of the first group of transistors and gates of the second group of transistors. In some examples, the first voltage is based on a supply voltage of the supply voltage node and a resistance of one or more first resistors coupled between the supply voltage node and the inverting input. In some examples, the current is based on a difference between a first current through the one or more first resistors and a second current through one or more second resistors, the one or more second resistors being coupled between the non-inverting input of the amplifier and the reference voltage node. In some examples, selectively coupling the inverting input to the non-inverting input of the amplifier includes providing the third voltage to gates of one or more third transistors, the one or more third transistors being coupled between the inverting input and the non-inverting input. In some examples, the method further comprises providing the current from the output to an amplifier circuit. In some examples, the amplifier circuit further includes a bias circuit configured to receive the current and generate a bias voltage based on the current.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a bias adder according to an example;

FIG. 2 illustrates a bias adder according to an example;

FIG. 3 illustrates a power amplifier circuit according to an example; and

FIG. 4 illustrates a telecommunication device according to an example.

### DETAILED DESCRIPTION

In examples disclosed herein, the output of an amplifier (such as a power amplifier) may depend on the bias provided to the amplifier. The bias may be a voltage, or, in some examples, a current. The bias provided to the amplifier may impact the slew rate of the amplifier. Slew rate generally refers to the maximum rate of change of the output of an amplifier, which means that a higher slew rate corresponds to the output of the amplifier changing at a faster rate, whereas slower slew rates corresponds to the output of the amplifier changing at a relatively slower rate. Furthermore, the bias provided to the amplifier may affect the dispersion (e.g., the change in wavelength over time of the signal output by the amplifier), and/or the gain of the amplifier. In many applications, dispersion is undesirable, slow (or low) slew rates are undesirable, and/or low gain (or increases in gain causing corresponding increases in dispersion) is undesirable. Examples of bias adders disclosed herein may alter the amount of bias provided to an amplifier (e.g., adjust the bias point of the amplifier), thereby improving the operation of amplifiers by adjusting slew rates, dispersion, and/or gain, as well as other characteristics of the amplifier.

In some examples of bias adders disclosed herein, the bias adders may also be configured to track changes in the driving voltage (e.g., the high voltage powering the amplifier), even as the driving voltage fluctuates or changes.

Bias adders and related systems disclosed herein may be especially useful or helpful with envelope tracking and/or average power tracking circuits, such as telecommunication devices or power amplifiers that are tied to or track a given signal, such as a high voltage (as will be discussed below).

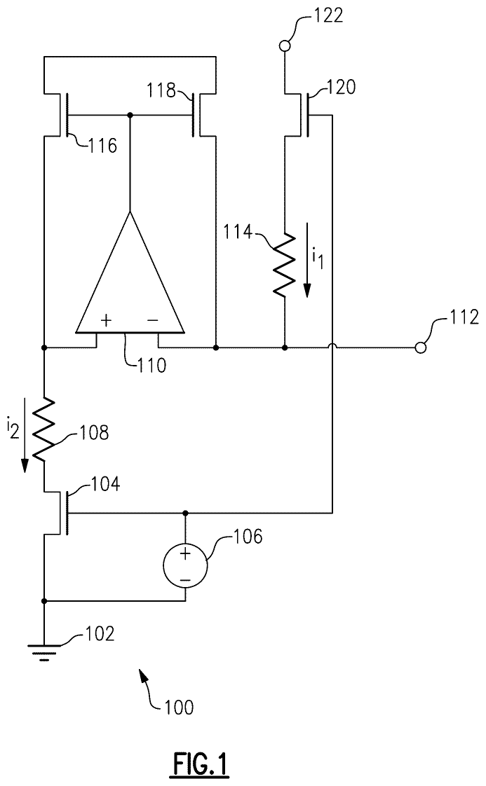

FIG. 1 illustrates a block diagram of a bias adder 100 according to an example. The bias adder 100 is configured to adjust the bias point of an amplifier, such as a power amplifier in an audio or telecommunication system.

The bias adder 100 includes a reference node 102, a first transistor 104, a voltage source 106, a non-inverting resistor 108, an amplifier 110, a bias node 112, an inverting resistor 114, a second transistor 116, a third transistor 118, a fourth transistor 120, and a high voltage node 122. The resistors 108, 114 may be collectives of resistors arranged in parallel and/or series, and may be trimmable (that is, the resistance of the resistors 108, 114 may be adjustable using trim techniques).

The reference node is coupled to a first drain or source of the first transistor 104 and to the voltage source 106. A second drain or source of the first transistor 104 is coupled to the non-inverting resistor 108. The voltage source 106 is coupled to a gate of the first transistor 104 and fourth transistor 120. The amplifier 110 has an inverting input, a non-inverting input, and an output. The output of the amplifier 110 is coupled to the gates of the second and third transistors 116, 118. The inverting input of the amplifier 110 is coupled to a second drain or source of the third transistor 118, the bias node 112, and the inverting resistor 114. The non-inverting input of the amplifier 110 is coupled to a second drain or source of the second transistor 116, and to the non-inverting resistor 108. The first drain or source of the second transistor 116 is coupled to the first drain or source of the third transistor 118. The inverting resistor 114 is coupled to the second drain or source of the fourth transistor 120, and the first drain or source of the fourth transistor 120 is coupled to the high voltage node 122.

The voltage source 106 is configured to selectively provide a first bias voltage to the gates of the first and fourth transistors 104, 120.

The high voltage node 122 is connected to a high or highest voltage in the system, and is configured to provide that voltage (e.g., Vcc) to the first drain or source of the fourth transistor 120.

The bias node 112 may be coupled to an external power amplifier or other amplifier, and may be configured to provide a second bias voltage or current to the external amplifier, thereby adjusting the bias point of the external amplifier.

Each transistor 104, 116, 118, 120, may function as a switch, and may have an open (e.g., non-conducting) state and a closed state (e.g., conducting state). The first transistor 104 and fourth transistor 120 may be open or closed depending on the bias voltage provided by the voltage source 106. The second transistor 116 and third transistor 118 may be open or closed depending on the voltage provided at the output of the amplifier 110.

When in the closed state, current may pass from one of the drain or source of a transistor to the other of the drain or source of that transistor. In the open state, current may be prevented (in whole or in substantial part) from passing from one of the drain or source of a given transistor to the other of the drain or source of the same transistor.

When the fourth transistor 120 is closed, a current (11) or portions of i₁ may pass from the high voltage node 122 through the inverting resistor 114 to the inverting input of the amplifier 110 and/or to the bias node 112. In some examples, i₁ or portions of i₁ may further pass through the second and third transistors 116, 118 (provided the second and third transistors 116, 118 are in a closed state) through the non-inverting resistor 108, and the first transistor 104 to the reference node 102.

In some examples, during time periods when the voltage at the bias node 112 is sufficiently high, the amplifier 110 may provide an output to the gates of the second and third transistors 116, 118, and/or the output of the amplifier 110 may rise sufficiently to turn on the second and third transistor 116, 118 (e.g., switch the second and third transistor 116, 118 to a closed state). In some examples, the output of the amplifier 110 may be based on a difference between the voltages of the inverting input and the non-inverting input.

It may be observed, in some examples, that when second and third transistors 116, 118 are in a closed state, the output of the amplifier 110 is connected to both the inverting and non-inverting inputs of the amplifier 110. In some examples, when the voltages are equal or near equal at both inputs to the amplifier 110, the output voltage of the amplifier 110 may fall to zero or to a near zero value, causing the second and third transistors 116, 118 to transition to an open state (e.g., turn off). When the second and third transistors 116, 118 are in an open state and the first and fourth transistors 104, 120 are in a closed state, the voltage at the non-inverting input of the amplifier 110 may change to be different from the voltage at the inverting input, thereby causing the output voltage of the amplifier 110 to increase until the second and third transistors 116, 118 are turned back on, pulling the voltage of the non-inverting input to equal the voltage of the inverting input, and so forth.

As the above illustrates, in some examples the amplifier 110 may behave in such a manner that when the amplifier turns on (e.g., provides an output sufficiently large to turn on the second and third transistor 116, 118), this will cause the amplifier 110 to pull the voltage at its own inputs (the non-inverting and inverting inputs) to the same voltage, which will cause the amplifier 110 to stop providing an output sufficient to turn on the second and third transistors 116, 118. When the second and third transistors 116, 118 turn off, the voltage difference between the inputs of the amplifier 110 may grow large enough that the amplifier 110 again provides an output, thus turning on the second and third transistors 116, 118, which again may cause the amplifier 110 to turn off. In other words, in some examples the amplifier 110 may be in a self-regulating feedback loop where the amplifier 110 turning on (e.g., providing an output sufficient to close the second and third transistors 116, 118) will cause the amplifier 110 to turn off. In this manner, the amplifier 110 may be made to automatically track certain voltage changes in the system (e.g., changes in the high voltage at the high voltage node 122).

The following equations may, in some examples, describe elements of the system when some or all of the transistors 104, 116, 118, 120 are in a closed state.

$${i}_{1} = \frac{{V}_{c c} - {V}_{b n}}{{R}_{i}} \qquad ( 1 )$$

$${i}_{2} = \frac{{V}_{b n} - {V}_{O}}{{R}_{n}} \qquad ( 2 )$$

$${V}_{O} = {V}_{B} + {V}_{g s} \qquad ( 3 )$$

where V_{cc} is the voltage provided by the high voltage node 122, V_{bn} is the voltage of the bias node 112, V_{O} is an offset voltage, VB is the voltage provided by the voltage source 106 to the gates of the first and fourth transistors 104, 120, V_{gs} is the gate-to-source voltage of the first transistor 104 (if the transistors 104, 116, 118, 120 are matched, V_{gs} may be the gate-to-source voltage of each transistor 104, 116, 118, 120), Rᵢ is the resistance of the inverting resistor 114, and Rₙ is the resistance of the non-inverting resistor 108. An output current, Iₒ, may be defined such that Iₒ=i₁−i₂, where Iₒ is the current going to or from the bias adder 100 through the bias node 112 to or from the external amplifier. Note that the equation for Iₒ assumes that i₂ is going out of (e.g., away from) the bias node 112 to the reference node 102 and Iₒ is similarly going away from the bias node 112 to the external amplifier, and thus subtracts i₂ from i₁. However, other sign conventions may be used depending on the assumed directions of the currents. In some examples, Iₒ is simply the portion of in that goes elsewhere than to the reference node 102 via the non-inverting resistor 108.

The current i₁ is provided when the fourth transistor 120 is closed. The fourth transistor 120 is closed when the first bias voltage (provided by the voltage source 106) is adequate to turn on the fourth transistor 120 (e.g., to put the fourth transistor 120 into a conducting state). Because the current i₁ is derived from the high voltage node 122, and the high voltage node 122 may be coupled to the same voltage or power supply rail that drives and/or powers the external amplifier, the bias voltage provided at the bias node 112 may track and/or account for changes in the voltage provided to the high voltage node 122 and/or for changes in the voltage used to power and/or drive the external amplifier.

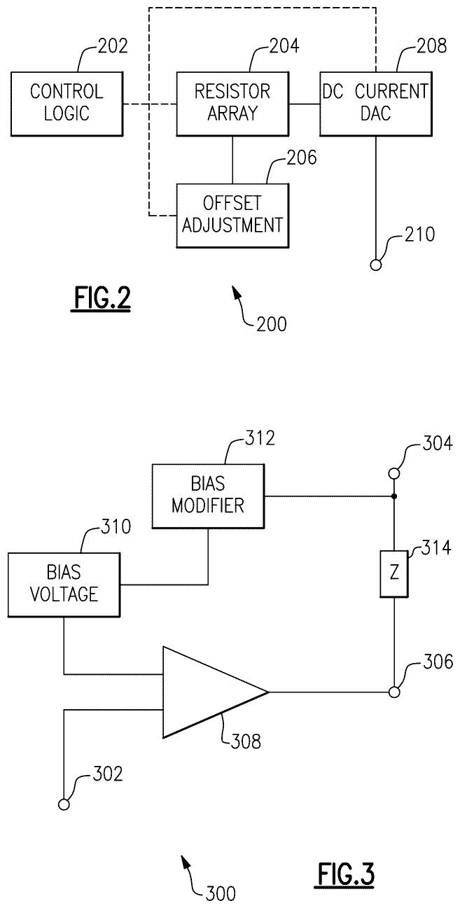

FIG. 2 illustrates a block diagram of a bias adder 200 according to an example. The bias adder 200 includes control logic 202, a resistor array 204, an offset adjustment circuit 206, a DC current digital-to-analog converter (DAC) 208 (“DAC 208”), and an output 210.

The control logic 202 is coupled to the resistor array 204, and may be optionally coupled to the offset adjustment circuit 206 or to the DAC 208. The resistor array 204 is coupled to the DAC 208 and to the offset adjustment circuit 206. The DAC 208 is coupled to the output 210.

The resistor array 204 may be used to control the slope of the curve corresponding to the gain of the bias adder 200. In some examples, the resistor array 204 is trimmable to allow correction for process variations that occur in the manufacture of the resistors of the array. The bias adder 200 output may control the gain dispersion and/or gain of the power amplifier (to which the bias adder 200 may be coupled) as well.

The resistor array 204 may contain one or more parallel branches which each contain one or more respective switching devices (e.g., transistors) coupled in series with one or more resistors, where each of the parallel branches is coupled to a reference node, ground node, or low voltage node (collectively, “reference node”). The switching devices may be used to selectively connect and/or disconnect resistors of the parallel branches to and/or from the reference node. In some examples, as more resistors are connected, the overall resistance of the one or more parallel branches falls, thus directing more current through the resistor array 204 to the reference node. As fewer resistors are connected, the overall resistance of the one or more parallel branches increases, thus directing less current through the resistor array 204 to the reference node. In some examples, the larger the number of parallel branches that are active (e.g., conducting), the more current is directed to the reference node and the less current is directed to the DAC 208. In some examples, the voltage at the input to the DAC 208 is proportional to the amount of current directed to the DAC 208 (and inversely proportional to the amount of current directed through the parallel branches of the resistor array 204 to the reference node—that is, as current through the parallel branches increases the input voltage to the DAC 208 decreases).

The offset adjustment circuit 206 controls a voltage offset provided to the resistor array 204 and/or DAC 208. In some examples, the offset adjustment circuit 206 controls when the bias adder 200 is on and when the bias adder 200 is off.

The DAC 208 may receive a digital representation of a signal and convert that digital representation into an analog signal and provide the signal to the output 210. In some examples, the DAC 208 may provide a DC current to the output 210.

In some examples, the DC current DAC 208 may correspond to the amplifier 110, the resistor array 204 may correspond to the non-inverting and/or inverting resistor 108, 114, and the offset adjustment circuit 206 may correspond to the voltage source 106.

The control logic 202 may control the trim level of the resistor array 204, and may be configured to control the DAC 208, offset adjustment circuit 206, and so forth. In various examples, the control logic 202 may be configured to keep the output of the bias adder 200 in phase with changes in the high voltage (for example, the high voltage provided at the high voltage node 122 of FIG. 1). In some examples, maintaining the high voltage and the bias adder 200 output in phase minimizes parasitic capacitances. In some examples, the output of the power amplifier, changes in the high voltage, and changes the output of the bias adder 200 all occur with a minimal or zero phase difference.

FIG. 3 illustrates a power amplifier system 300 (“system 300”) with a bias modifier according to an example. In this system, a bias modifier (for example, bias adder 100 of FIG. 1) may adjust the bias voltage provided to a power amplifier.

The system 300 includes a first input node 302 configured to provide a first input signal (which may be a voltage or current) to the power amplifier 308. The system 300 further includes a high voltage node 304 configured to provide a voltage signal that may be constant or may vary with time to the bias modifier 312. The system includes a bias voltage circuit 310, an impedance 314, and an output 306.

The bias modifier 312 is coupled to the high voltage node 304 and the bias voltage circuit 310. The bias voltage circuit 310 is coupled to a first input of the power amplifier 308. The first node 302 is coupled to a second input of the power amplifier 308. The output of the power amplifier 308 is coupled to the output 306. The impedance 314 is coupled between the high voltage node 304 and the output 306.

The bias modifier 312 may be implemented using the bias adder 100 of FIG. 1 in some examples. In some examples, both the bias modifier 312 and the bias voltage circuit 310 may include or be implemented using the bias adder 100 of FIG. 1.

The bias voltage circuit 310 provides a first voltage to the first input of the power amplifier 308, and the first input node 302 provides a second voltage to the second input of the power amplifier 308. The first and second voltages are typically different, and may be positive, negative, and/or zero. The output and/or performance of the power amplifier 308 may depend on the difference between the first and second voltage.

For example, the power amplifier 308 may turn on or off depending on the difference between the first and second voltage. For example, the power amplifier 308 may turn on when the difference is greater than a given threshold voltage, and the power amplifier 308 may turn off when the difference is less than a given threshold voltage.

The rate at which the power amplifier 308 is able to switch between off and on states, and/or the rate at which the power amplifier 308 is able to switch between positive polarity and negative polarity outputs may also depend on the first and second voltage and/or the difference between the first and second voltages. For example, the slew rate of the power amplifier 308 may be controlled or adjusted using the first and/or second voltages. In some examples, the slew rate of the power amplifier 308 may depend on how long it takes a voltage at one of the inputs to change such that the difference between the voltages exceeds or falls below the threshold voltage. By adjusting the bias voltage using the bias modifier 312, the bias voltage (e.g., the first voltage which is provided by the bias voltage circuit 310 to the first input of the power amplifier 308) may be driven lower or higher. In examples where the first voltage is driven lower, the difference between the first and second voltage may decrease more rapidly. Likewise, when the first voltage is driven higher, the difference between the first and second voltage may increase more rapidly.

Furthermore, the current-voltage gain characteristic curve (e.g., mA/V) of the power amplifier 308 may, in some examples, be adjusted using the bias modifier 312. For example, the transconductance of the power amplifier 308 may be adjusted by adjusting the first voltage, and the rate of change of transconductance curve of the power amplifier 308 may be similarly controlled.

The bias modifier 312 may adjust the bias voltage (e.g., the first voltage) depending on the bias voltage provided by the bias voltage circuit 310 and the high voltage provided by the high voltage node 304. For example, if the high voltage of the high voltage node 304 fluctuates or changes over time, the bias adjustment performed by the bias modifier 312 may track the fluctuations in the high voltage.

As mentioned above, the phase differences between the high voltage at the high voltage node 304, the output of the bias modifier 312, and/or the output of the power amplifier 308 are all minimized (that is, the phase differences are zero or near zero). The impedance 314 may be a phase-dependent reactance and may be a physical component (such as an inductor), or may be an induced element (e.g., due to electromagnetic coupling between an input bus and an output bus located near one another).

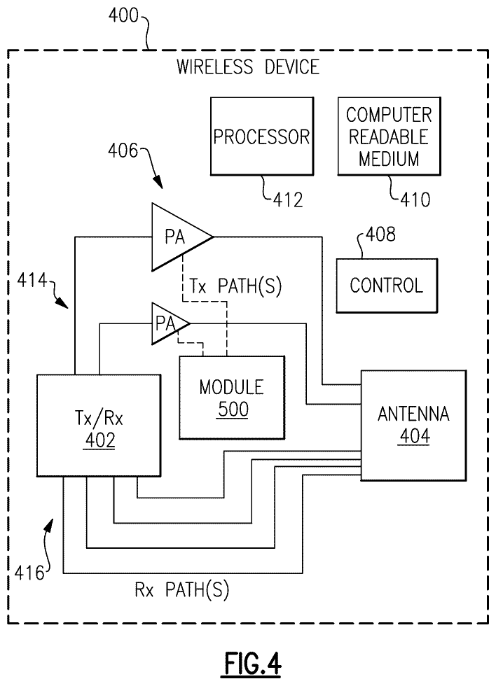

FIG. 4 is a block diagram of one example of a wireless communications device 400 in which the example bias adders 100, 200 or power amplifier system 300 can be used. The example wireless device 400 can be a mobile phone, such as a smart phone, for example. By way of example, the wireless device 400 can communicate in accordance with various protocols, including LTE, 4G, 5G, some protocols still in development, and so forth. The wireless device 400 can alternatively or additionally be configured to communicate in accordance with one or more other communication standards, including but not limited to one or more of a Wi-Fi standard, a Bluetooth standard, a 3G standard, a 4G standard or an Advanced LTE standard.

As illustrated in FIG. 4, the wireless device 400 can include a transceiver 402, an antenna 404, power amplifiers 406, a control component 408, a computer readable storage medium 410, and at least one processor 412. The bias adders 100, 200 and/or power amplifier system 300 can be electrically coupled to one or more components of the of the power amplifiers 406. As will be appreciated by those skilled in the art, the wireless device 400 can include elements that are not illustrated in FIG. 4 and/or a sub-combination of the illustrated elements.

The transceiver 402 can generate radio-frequency signals for transmission via the antenna 404. Furthermore, the transceiver 402 can receive incoming radio-frequency signals from the antenna 404. It will be understood that various functionalities associated with transmitting and receiving of radio-frequency signals can be achieved by one or more components that are collectively represented in FIG. 4 as the transceiver 402. For example, a single component can be configured to provide both transmitting and receiving functionalities. In another example, transmitting and receiving functionalities can be provided by separate components.

In FIG. 4, one or more output signals from the transceiver 402 are depicted as being provided to the antenna 404 via one or more transmission paths 414. In the example illustrated, different transmission paths 414 can represent output paths associated with different frequency bands (e.g., a high band and a low band) and/or different power outputs. Similarly, one or more signals from the antenna 404 are depicted as being provided to the transceiver 402 via one or more receive paths 414. In the example illustrated, different receive paths 416 can represent paths associated with different signaling modes and/or different receive frequency bands. The wireless device 400 can be adapted to include any suitable number of transmission paths 414 or receive paths 416. The transmission paths 414 can include one or more power amplifiers 406 to aid in boosting a radio-frequency signal having a relatively low power to a higher power suitable for transmission. Each power amplifier may include its own bias adder 100, 200 or they may all share a bias adder 100, 200. Each power amplifier may be incorporated into or represent a power amplifier system 300 as well.

In certain embodiments, the at least one processor 412 can be configured to facilitate implementation of various processes on the wireless device 400. The at least one processor 412 can be, for example, implemented using hardware, software, or a combination of hardware and software. For instance, the at least one processor 412 may include one or more microprocessors or other types of controllers that can perform a series of instructions that manipulate data. However, in other examples the processor 412 may include specially-programmed, special-purpose hardware, such as for example, an application-specific integrated circuit (ASIC) tailored to perform a particular operations disclosed herein. In certain implementations, the wireless device 400 can include a non-transitory computer readable medium 410, such as a memory, which can store computer program instructions that may be provided to and executed by the at least one processor 412.

In various examples, a controller (such as the control logic 202) may control the bias modifier 312 and/or bias adder 100. The bias modifier 312 and/or bias adder 100 may be programmable and/or reprogrammable.

In some examples, the amplifier 110 of FIG. 1 may be implemented as a DAC or similar device.

In the foregoing examples, the bias adders and/or modifiers may adjust the bias voltage by increasing or decreasing the bias voltage (e.g., add or subtract from the bias voltage).

Examples of the methods and systems discussed herein are not limited in application to the details of construction and the arrangement of components set forth in the description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Various controllers, such as the processor 412, may execute various operations discussed above. Using data stored in associated memory and/or storage, the processor 412 also executes one or more instructions stored on one or more non-transitory computer-readable media, which the processor 412 may include and/or be coupled to, that may result in manipulated data. In some examples, the processor 412 may include one or more processors or other types of processors. In one example, the processor 412 is or includes at least one processor. In another example, the processor 412 performs at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more processors and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

What is claimed is:

1. A bias adder system comprising:
an amplifier;
an input node configured to receive a supply voltage;
an output node coupled to an inverting input of the amplifier and configured to provide an output current;
a reference node configured to provide a reference voltage;
a first transistor coupled between the input node and the inverting input of the amplifier; and
a second transistor coupled between the reference node and a non-inverting input of the amplifier.

2. The bias adder system of claim 1 wherein the bias adder system further comprises a third transistor and a fourth transistor coupled in series with one another between the inverting input and the non-inverting input of the amplifier.

3. The bias adder system of claim 2 wherein the bias adder system further comprises a power source coupled to the reference node and to a first gate of the first transistor and a second gate of the second transistor, the power source being configured to provide a first gate voltage to the first gate and the second gate.

4. The bias adder system of claim 3 wherein an output of the amplifier is coupled to a third gate of the third transistor and to a fourth gate of the fourth transistor.

5. The bias adder system of claim 4 wherein the bias adder system further comprises a first resistor coupled between the first transistor and the inverting input of the amplifier, and a second resistor coupled between the second transistor and the non-inverting input of the amplifier.

6. The bias adder system of claim 5 wherein the output node is further coupled to a power amplifier circuit and configured to provide the output current to an input of the power amplifier circuit to adjust a bias voltage of the power amplifier circuit.

7. The bias adder system of claim 6 wherein the power amplifier circuit includes a bias circuit configured to receive the output current and to generate a bias voltage based at least in part on the output current.

8. A system for adjusting a bias voltage of an amplifier, comprising:
a resistor array;
a DC current DAC coupled to the resistor array;
an offset adjustment circuit coupled to the resistor array;
an output coupled to the DC current DAC; and
a controller.

9. The system of claim 8 wherein the output is further coupled to an amplifier circuit and is configured to provide a current to an input of the amplifier circuit.

10. The system of claim 9 wherein the amplifier circuit includes a bias circuit coupled to the output and configured to generate a bias voltage based at least in part on the current.

11. The system of claim 8 wherein the controller is configured to control a trim of the resistor array, and to control the offset adjustment circuit to provide a voltage offset to the resistor array to determine a bias level of the DC current DAC.

12. The system of claim 9 wherein the DC current DAC is configured to provide a current to the output.

13. A method for providing a bias voltage comprising:
selectively opening and closing a first group of transistors coupled between an inverting input of an amplifier and a supply voltage node;
selectively opening and closing a second group of transistors coupled between a non-inverting input of the amplifier and a reference voltage node;
providing a first voltage at the inverting input based on an open or closed state of the first group of transistors;
providing a second voltage at the non-inverting input based on an open or closed state of the second group of transistors;
providing a third voltage at an output of the amplifier, the third voltage being based at least in part on a difference between the first voltage and the second voltage;
selectively coupling the inverting input to the non-inverting input of the amplifier based on the third voltage; and
providing a current at an output, the current being based on the first voltage, the second voltage, and the third voltage.

14. The method of claim 13 wherein selectively opening and closing the first group of transistors and selectively opening and closing the second group of transistors is based on a duty cycle of a power source.

15. The method of claim 14 wherein the power source is configured to provide a control voltage to gates of the first group of transistors and gates of the second group of transistors.

16. The method of claim 13 wherein the first voltage is based on a supply voltage of the supply voltage node and a resistance of one or more first resistors coupled between the supply voltage node and the inverting input.

17. The method of claim 16 wherein the current is based on a difference between a first current through the one or more first resistors and a second current through one or more second resistors, the one or more second resistors being coupled between the non-inverting input of the amplifier and the reference voltage node.

18. The method of claim 13 wherein selectively coupling the inverting input to the non-inverting input of the amplifier includes providing the third voltage to gates of one or more third transistors, the one or more third transistors being coupled between the inverting input and the non-inverting input.

19. The method of claim 13 further comprising providing the current from the output to an amplifier circuit.

20. The method of claim 19 wherein the amplifier circuit further includes a bias circuit configured to receive the current and generate a bias voltage based on the current.
